(19) United States
(12) Patent Application Publication
(10) Pub. No.: US 2026/0043170 A1
(43) Pub. Date: Feb. 12, 2026

(54) EPITAXIAL SILICON AND DOPED SILICON GERMANIUM SUPERLATTICE AND METHODS FOR PREPARING THE SAME

(71) Applicant: Applied Materials, Inc., Santa Clara, CA (US)

(72) Inventors: Ruiying HAO, Santa Clara, CA (US); Chang Seok KANG, San Jose, CA (US); Raghuveer Satya MAKALA, Santa Clara, CA (US); Fredrick FISHBURN, Aptos, CA (US); Amy CHILD, Gansevoort, NY (US); Balasubramanian PRANATHARTHIHARAN, Santa Clara, CA (US)

(21) Appl. No.: 19/245,121

(22) Filed: Jun. 20, 2025

Related U.S. Application Data
(60) Provisional application No. 63/681,961, filed on Aug. 12, 2024.

(51) Int. Cl. C30B 29/06; C30B 25/14; C30B 25/22; C30B 29/08; C30B 29/68

(52) U.S. Cl. CPC C30B 29/06; C30B 25/14; C30B 25/22; C30B 29/08; C30B 29/68

(57) ABSTRACT

Embodiments of the present disclosure generally relate to epitaxial film stacks and vapor deposition processes for preparing the epitaxial film stacks. In one or more embodiments, a multi-layered epitaxial stack is disposed on a substrate, and the multi-layered epitaxial stack contains a plurality of doped silicon-germanium and silicon mini-stacks. Each of the doped silicon germanium stack contains a doped-silicon-germanium layer disposed between a first silicon-germanium layer and a second silicon-germanium layer. Each of the doped-silicon-germanium layers independently contains a concentration of a dopant which may vary or be the same between each of the doped-silicon-germanium layers. The multi-layered epitaxial stack has a dopant gradient based on the concentration of the dopant within each of the doped-silicon-germanium layers such that the multi-layered epitaxial stack has a wafer bow value at a predetermined threshold. The multi-layered epitaxial stack may be used throughout the microelectronics industry.

### CROSS-REFERENCE TO RELATED APPLICATIONS

This application claims priority to U.S. Prov. Appl. No. 63/681,961, filed on Aug. 12, 2024, which is herein incorporated by reference in its entirety.

### BACKGROUND

### Field

Embodiments of the present disclosure generally relate to film stacks and vapor deposition, and more specifically, epitaxial film stacks with doped layers and vapor deposition processes for preparing the epitaxial film stacks.

### Description of the Related Art

Microelectronic technology has advanced at a rapid pace and device dimensions have shrunk with advancing technology to provide faster processing and storage per unit space. As microelectronic technology advances, the market demands increasing smaller chips with increasingly more structures per unit area. One class of devices which has seen many advances in miniaturization are memory devices.

Two of the mainstays of the memory segment are NOT-AND (NAND) flash and dynamic random-access memory (DRAM), such as three-dimensional DRAM (3D-DRAM). DRAM is dynamic, volatile and very fast, making it well suited for short term system memory. DRAM has continued the path of scaling to smaller cell designs. This dimension shrink has driven the introduction of multiple patterning technology. Many of the DRAM devices contain epitaxial film stacks. Any crystal imperfections and/or defects cause leakage in the DRAM device and therefore a roadblock for the taller film stacks desired for 3D-DRAM over 2D-DRAM.

Therefore, a need exists for improved epitaxial film stacks with doped layers and vapor deposition processes for preparing the epitaxial film stacks.

### BRIEF DESCRIPTION OF THE DRAWINGS

So that the manner in which the above recited features of the present disclosure may be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a workpiece containing a multi-layered epitaxial stack disposed on a substrate, according to one or more embodiments described and discussed herein.

FIG. 2 is a flowchart depicting a method for fabricating a multi-layered epitaxial stack, according to one or more embodiments described and discussed herein.

FIG. 3 is a graph depicting a carbon concentration across a plurality of doped silicon-germanium and silicon mini-stacks for five examples, according to one or more embodiments described and discussed herein.

FIG. 4 is a graph depicting a carbon concentration across a plurality of doped silicon-germanium and silicon mini-stacks for three additional examples, according to one or more embodiments described and discussed herein.

FIGS. 5A-5C depict a process flow of a workpiece containing a multi-layered epitaxial stack disposed on a substrate being processed to remove the doped silicon germanium stacks retain the epitaxial-silicon layers, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### SUMMARY

Embodiments of the present disclosure generally relate to epitaxial film stacks and vapor deposition processes for preparing the epitaxial film stacks. In one or more embodiments, a film stack is provided and includes a plurality of mini-stacks disposed on a substrate, each mini-stack contains a first silicon-containing layer, a doped silicon-containing layer over the first silicon-containing layer, the doped silicon-containing layer comprising a dopant, a second silicon-containing layer over the doped silicon-containing layer, and a silicon layer over the second silicon-containing layer. The dopant has a gradient across the mini-stacks such that a concentration of dopant in the doped silicon-containing layer is different between a first film stack and a second film stack of the plurality of mini-stacks.

In some embodiments, a multi-layered epitaxial stack is disposed on a substrate, and the multi-layered epitaxial stack contains a plurality of doped silicon-germanium and silicon mini-stacks. Each of the doped silicon germanium stack contains a doped-silicon-germanium layer disposed between a first silicon-germanium layer and a second silicon-germanium layer. Each of the doped-silicon-germanium layers independently contains a concentration of a dopant which may vary or be the same between each of the doped-silicon-germanium layers. The multi-layered epitaxial stack has a dopant gradient based on the concentration of the dopant within each of the doped-silicon-germanium layers such that the multi-layered epitaxial stack has a wafer bow value at a predetermined threshold. The multi-layered epitaxial stack may be used throughout the microelectronics industry.

In one or more embodiments, a workpiece is provided and contains a multi-layered epitaxial stack disposed on a substrate, and the multi-layered epitaxial stack contains a plurality of doped silicon-germanium and silicon mini-stacks. Each of the doped silicon-germanium and silicon mini-stacks contains a doped silicon germanium stack and an epitaxial-silicon layer. Each of the doped silicon germanium stack contains a doped-silicon-germanium layer disposed between a first silicon-germanium layer and a second silicon-germanium layer. Each of the doped-silicon-germanium layers independently contains a concentration of a dopant in a range from about 0.01 atomic percent (at %) to about 5 at %, and the dopant contains carbon, boron, or a combination of carbon and boron. The multi-layered epitaxial stack has a dopant gradient based on the concentration of the dopant within each of the doped-silicon-germanium layers.

In other embodiments, a workpiece is provided and contains a multi-layered epitaxial stack disposed on a substrate, where the multi-layered epitaxial stack contains a plurality of doped silicon-germanium and silicon mini-stacks which contains about 10 stacks to about 250 stacks, for example, about 30 stacks to about 100 stacks. Each of the doped silicon-germanium and silicon mini-stacks contains a doped silicon germanium stack and an epitaxial-silicon layer. Each of the doped silicon germanium stack contains a doped-silicon-germanium layer disposed between a first silicon-germanium layer and a second silicon-germanium layer. Each of the doped-silicon-germanium layers independently contains a concentration of a dopant in a range from about 0.01 atomic percent (at %) to about 3 at % and the dopant contains carbon, boron, or a combination of carbon and boron. The multi-layered epitaxial stack has a dopant gradient based on the concentration of the dopant within each of the doped-silicon-germanium layers.

In some embodiments, a method of fabricating a film stack is provided and includes sequentially depositing a doped silicon germanium stack and an epitaxial-silicon layer to form a doped silicon-germanium and silicon mini-stack disposed on a substrate during a deposition cycle, and repeating the deposition cycle to prepare a multi-layered epitaxial stack comprising a plurality of the doped silicon-germanium and silicon mini-stacks on the substrate. Each of the doped silicon germanium stacks contains a doped-silicon-germanium layer disposed between a first silicon-germanium layer and a second silicon-germanium layer. Each of the doped-silicon-germanium layers independently contains a concentration of a dopant in a range from about 0.01 atomic percent (at %) to about 5 at %, and the dopant contains carbon, boron, or a combination of carbon and boron. The multi-layered epitaxial stack has a dopant gradient based on the concentration of the dopant within each of the doped-silicon-germanium layers.

### DETAILED DESCRIPTION

Embodiments of the present disclosure generally relate to epitaxial film stacks and vapor deposition processes for preparing the epitaxial film stacks. In one or more embodiments, a multi-layered epitaxial stack is disposed on a substrate, and the multi-layered epitaxial stack contains a plurality of doped silicon-germanium and silicon mini-stacks. In one or more embodiments, each of the doped silicon germanium stack contains a doped-silicon-germanium layer disposed between a first silicon-germanium layer and a second silicon-germanium layer. In other embodiments, each of the doped silicon germanium stack contains a doped-silicon-germanium layer disposed between a first silicon layer and a second silicon layer. Each of the doped-silicon-germanium layers independently contains a concentration of a dopant which may vary or be the same between each of the doped-silicon-germanium layers. The dopant contains carbon, boron, or a combination of carbon and boron. Also, the multi-layered epitaxial stack has a dopant gradient based on the concentration of the dopant within each of the doped-silicon-germanium layers such that the multi-layered epitaxial stack has a wafer bow value at a predetermined threshold.

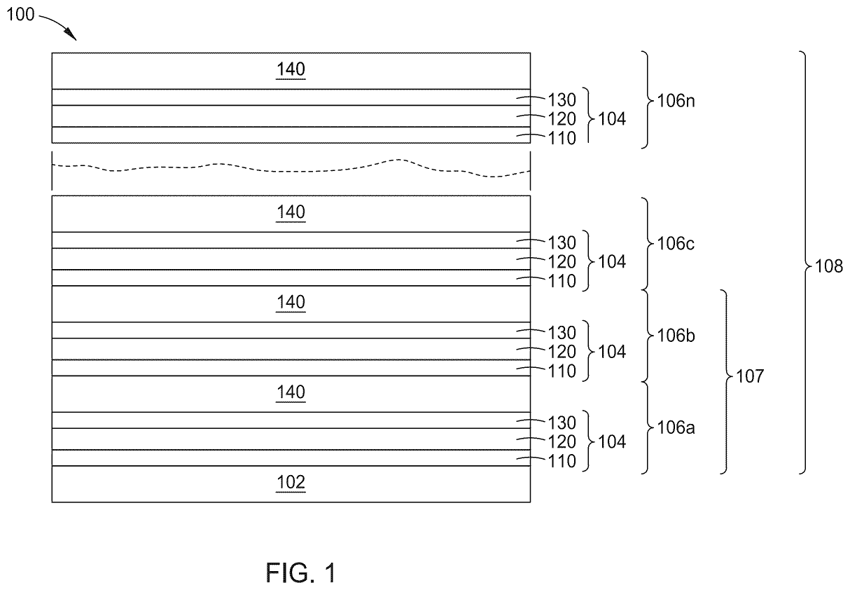

FIG. 1 depicts a workpiece 100 containing a multi-layered epitaxial stack 108 disposed on a substrate 102, according to one or more embodiments described and discussed herein. The multi-layered epitaxial stack 108 contains a plurality of or two, three, or more of doped silicon-germanium and silicon mini-stacks 106 (collectively). FIG. 1 depicts the four doped silicon-germanium and silicon mini-stacks 106a, 106b, 106c, and 106n, where there may be from 0 to about 250 or more of the doped silicon-germanium and silicon mini-stacks 106 disposed between the doped silicon-germanium and silicon mini-stack 106c and the doped silicon-germanium and silicon mini-stack 106n to form the multi-layered epitaxial stack 108. In one or more embodiments, the multi-layered epitaxial stack 108 contains two neighboring pairs 107 of the doped silicon-germanium and silicon mini-stacks 106 which may the same dopant concentration or different dopant concentrations. In other embodiments, a plurality of mini-stacks may be or include the plurality of doped silicon-germanium and silicon mini-stacks 106 and/ or the multi-layered epitaxial stack 108.

Each of the doped silicon-germanium and silicon mini-stacks 106 contains (a first silicon-containing layer, a doped silicon-containing layer, a second silicon-containing layer) or a doped silicon germanium stack 104 and (a silicon layer) or an epitaxial-silicon layer 140. Typically, the epitaxial-silicon layer 140 is disposed on the doped silicon germanium stack 104, however their order may be reversed such that the doped silicon germanium stack 104 is disposed on the epitaxial-silicon layer 140. In one or more examples, a first silicon-containing layer, a doped silicon-containing layer, and a second silicon-containing layer may be or include the doped silicon germanium stack 104.

Each of the doped silicon germanium stacks 104 contains a doped-silicon-germanium layer 120 disposed between a first silicon-germanium layer 110 and a second silicon-germanium layer 130, as disclosed and described in one or more embodiments. The epitaxial-silicon layer 140 contains one or more silicon materials, such as epitaxial silicon, crystalline silicon, pure silicon, intrinsic silicon, undoped silicon, any dopant thereof, or any combination thereof. In some examples, the first silicon-germanium layer 110 and the second silicon-germanium layer 130 have the same composition, but in other example, the first silicon-germanium layer 110 and the second silicon-germanium layer 130 may have different compositions relative to each other. In other embodiments, not shown in the Figures, each of the doped silicon germanium stacks 104 may contain the doped-silicon-germanium layer 110 disposed between a first silicon layer (instead of the first silicon-germanium layer 110) and a second silicon layer (instead of the second silicon-germanium layer 130).

In some embodiments, a first silicon-containing layer may be or include the first silicon-germanium layer 110, a doped silicon-containing layer may be or include the doped-silicon-germanium layer 120, a second silicon-containing layer may be or include the second silicon-germanium layer 130, and a silicon layer may be or include the epitaxial-silicon layer 140. Each of the doped silicon-germanium and silicon mini-stacks 106 may contain a first silicon-containing layer, a doped silicon-containing layer, a second silicon-containing layer (e.g., the doped silicon germanium stack 104) and a silicon layer (e.g., the epitaxial-silicon layer 140).

In one or more embodiments, each of the doped-silicon-germanium layers 120 throughout the multi-layered epitaxial stack 108 may independently have a concentration of dopant the same, less than, or greater than each of its neighboring doped-silicon-germanium layer 120. As such, the multi-layered epitaxial stack 108 has a dopant gradient based on the concentration of the dopant within each of the doped-silicon-germanium layers 120. The dopant may be or include carbon, boron, or a combination of carbon and boron within each of the doped-silicon-germanium layers 120 throughout the multi-layered epitaxial stack 108. The type of dopant and/or the amount of dopant may be adjusted in each independent doped-silicon-germanium layer 120 so to control the dopant gradient, and as such, adjust the wafer bow value across the multi-layered epitaxial stack 108. The wafer bow value may be about or less than 600 μm, about or less than 550 μm, or about or less than 500 μm, such as about 10 μm to about or less than 400 μm. In some examples, the wafer bow value of the multi-layered epitaxial stack 108 may be about 10 μm to about or less than 300 μm, about 10 μm to about or less than 200 μm, about 10 μm to about or less than 150 μm, or about 10 μm to about or less than 100 μm.

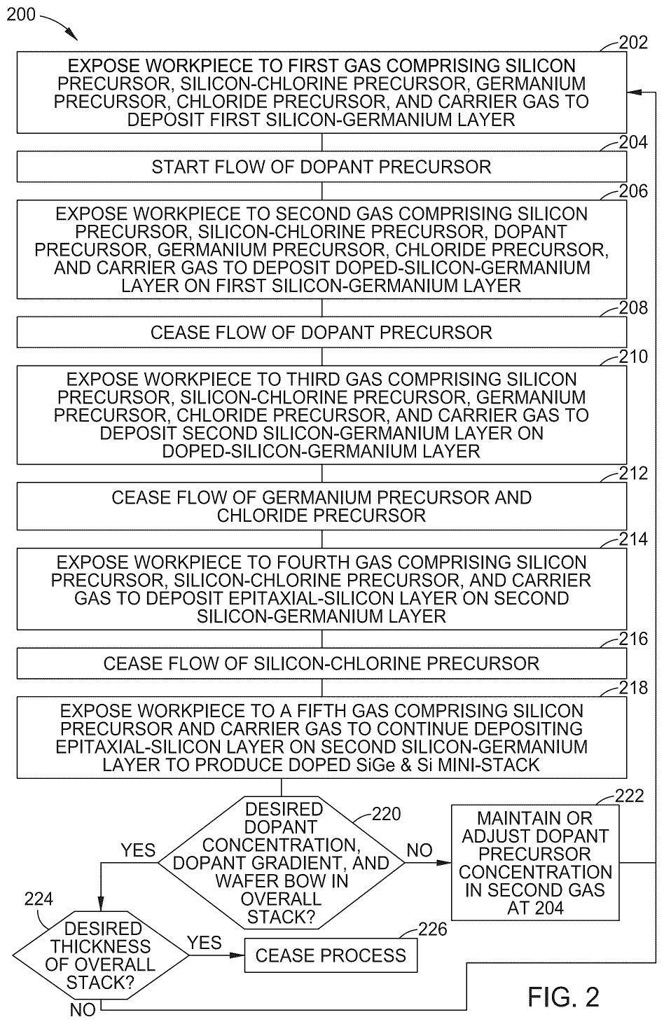

FIG. 2 is a flowchart depicting a process or method 200 for fabricating a multi-layered epitaxial stack, such as the multi-layered epitaxial stack 108 disposed on the substrate 102, according to one or more embodiments described and discussed herein. The method 200 includes operations 202-226, as provided in FIG. 2. Other multi-layered epitaxial stacks and various film stacks may be deposited, fabricated, or otherwise produced by the method 200.

In one or more embodiments, the method 200 is provided and includes sequentially depositing a doped silicon germanium stack 104 and an epitaxial-silicon layer 140 to form a doped silicon-germanium and silicon mini-stack 106 disposed on a substrate 102 during a deposition cycle. The method 200 includes repeating the deposition cycle to prepare a multi-layered epitaxial stack 108 containing two, three, or more of the doped silicon-germanium and silicon mini-stacks 106 on the substrate 102.

At operation 202 of the method 200, the deposition cycle includes exposing the workpiece 100 containing the substrate 102 to a first gas containing a silicon precursor, a silicon-chlorine precursor, a germanium precursor, a chloride precursor, and a carrier gas to deposit a first silicon-germanium layer 110. The silicon precursor may be or contain one or more of silane, disilane, trisilane, tetrasilane, or any combination thereof. The silicon-chlorine precursor may be or contain one or more of monochlorosilane, dichlorosilane, trichlorosilane, tetracholorosilane, hexachlorodisilane, or any combination thereof. The germanium precursor may be or contain one or more of germane, digermane, tetrachlorogermane, one or more organogermane compounds, or any combination thereof. The chlorine precursor may be or contain one or more of hydrogen chloride, chlorine (Cl₂), or any combination thereof. The carrier gas may be or contain on or more of hydrogen (H₂), nitrogen (N₂), argon, helium, or any combination thereof. In some examples, the carrier gas contains a mixture of hydrogen and nitrogen. The mixture of hydrogen and nitrogen may have a hydrogen to nitrogen molar ratio in a range from about 1:10 to about 10:1, about 1:5 to about 5:1, about 1:3 to about 3:1, about 1:2 to about 2:1, or about 1:1.

At operation 204 of the method 200, the deposition cycle includes starting a flow of one or more dopant precursors into the processing region. The dopant precursor may be or contain one or more carbon precursors, one or more silicon-carbon precursors, one or more boron precursors, a combination of one or more carbon precursors and one or more boron precursors or a combination of one or more silicon-carbon precursors and one or more boron precursors. In some examples, the dopant precursor may be or contain one or more carbon precursors, one or more silicon-carbon precursors, or a combination of the carbon precursor and the silicon-carbon precursor. The silicon-carbon precursor may be or contain one or more alkylsilanes, such as monomethylsilane (MMS), dimethylsilane, or any combination thereof. In other examples, the dopant precursor may be or contain one or more boron precursors. Exemplary boron precursor may be or contain diborane, trimethylborane, triethylborane, boron trichloride, or any combination thereof.

At operation 206 of the method 200, the deposition cycle includes exposing the workpiece 100 to a second gas containing the silicon precursor, the silicon-chlorine precursor, the dopant precursor, the germanium precursor, the chloride precursor, and the carrier gas to deposit a doped-silicon-germanium layer 120 on the first silicon-germanium layer 110.

At operation 208 of the method 200, the deposition cycle includes ceasing or otherwise stopping the flow of the dopant precursor into the process region.

At operation 210 of the method 200, the deposition cycle includes exposing the workpiece 100 to a third gas containing the silicon precursor, the silicon-chlorine precursor, the germanium precursor, the chloride precursor, and the carrier gas to deposit a second silicon-germanium layer 130 on the doped-silicon-germanium layer 120.

At operation 212 of the method 200, the deposition cycle includes ceasing or otherwise stopping the flow of the germanium precursor and the chloride precursor into the process region.

At operation 214 of the method 200, the deposition cycle includes exposing the workpiece 100 to a fourth gas containing the silicon precursor, the silicon-chlorine precursor, and the carrier gas to deposit the epitaxial-silicon layer 140 on the second silicon-germanium layer 130.

At operation 216 of the method 200, the deposition cycle includes ceasing or otherwise stopping the flow of the silicon-chlorine precursor into the process region.

At operation 218 of the method 200, the deposition cycle includes exposing the workpiece 100 to a fifth gas containing the silicon precursor and the carrier gas to continue depositing or otherwise forming the epitaxial-silicon layer 140 on the second silicon-germanium layer 130.

At operation 220 of the method 200, the deposition cycle includes determining if the desired values have been reach for one or more of the following: the concentration of the dopant throughout the doped-silicon-germanium layer 120, the dopant gradient throughout the multi-layered epitaxial stack 108, the wafer bow of the multi-layered epitaxial stack 108, or any combination thereof. In one or more examples, the wafer bow of the multi-layered epitaxial stack 108 is the determining variable to decide to advance to operation 222 or 224. In some examples, the dopant gradient throughout the multi-layered epitaxial stack 108 is the determining variable to decide to advance to operation 222 or 224. In other examples, the concentration of the dopant throughout the doped-silicon-germanium layer 120 is the determining variable to decide to advance to operation 222 or 224. Overall, the multi-layered epitaxial stack 108 has a dopant gradient based on the concentration of the dopant within each of the doped-silicon-germanium layers 120.

In one aspect, if the desired values for one, two, or three of these variable have not been reached at operation 220, such that the determination is “NO”, then at operation 222 the concentration of the dopant precursor at operation 204 may be adjusted (e.g., increased or decreased) or maintained the same and the operations 202-220 may be repeated as many times to reach the desired wafer bow of the multi-layered epitaxial stack 108, the desired dopant gradient throughout the multi-layered epitaxial stack 108, and/or the desired concentrations of dopant in each of the independent doped-silicon-germanium layers 120.

In another aspect, if the desired values for one, two, or three of these variable have been reached at operation 220, such that the determination is “YES”, then the method 200 proceeds to operation 224.

At operation 224 of the method 200, the desired thickness of the multi-layered epitaxial stack 108 is determined. In one aspect, if the desired thickness of the multi-layered epitaxial stack 108 has not been reached, such that the determination is “NO”, then the operations 202-222 may be repeated as many times to reach the desired thickness of the multi-layered epitaxial stack 108.

In another aspect, if the desired thickness of the multi-layered epitaxial stack 108 has been reached, such that the determination is “YES”, then the method 200 proceeds to operation 226.

At operation 226 of the method 200, the overall process of method 200 is ceased or otherwise stopped.

Operations 202-226 may be repeated as many times as desired for preparing the multi-layered epitaxial stack 108 containing the desired number of the doped silicon-germanium and silicon mini-stacks 106 on the substrate 102. The deposition cycle is repeated in a range from about 1, 2, 3, 4, 5, 6, 8, 10, about 12, about 15, about 20, about 25, about 30, about 40, or about 50 times to about 60, about 70, about 80, about 90, about 100, about 120, about 140, about 150, about 160, about 180, about 200, about 250, about 300, or more times to prepare the multi-layered epitaxial stack 108. For example, the deposition cycle may be repeated from about 2 times to about 300 times, about 2 times to about 250 times, about 5 times to about 200 times, about 10 times to about 200 times, about 20 times to about 200 times, about 30 times to about 200 times, about 40 times to about 200 times, about 50 times to about 200 times, about 80 times to about 200 times, about 100 times to about 200 times, about 120 times to about 200 times, about 150 times to about 200 times, about 180 times to about 200 times, about 5 times to about 100 times, about 10 times to about 100 times, about 20 times to about 100 times, about 30 times to about 100 times, about 40 times to about 100 times, about 50 times to about 100 times, about 60 times to about 100 times, about 80 times to about 100 times, or about 90 times to about 100 times to prepare the multi-layered epitaxial stack 108.

In one or more examples, the deposition cycle, including operations 202-226, may be repeated from about 5 times to about 300 times to prepare the multi-layered epitaxial stack 108. In other examples, the deposition cycle may be repeated from about 10 times to about 250 times to prepare the multi-layered epitaxial stack 108. In some examples, the deposition cycle may be repeated from about 30 times to about 100 times to prepare the multi-layered epitaxial stack 108.

FIG. 1 depicts the workpiece 100 containing the multi-layered epitaxial stack 108 disposed on the substrate 102. The substrate 102 may be or include any suitable substrate material. In one or more embodiments, the substrate 102 contains one or more semiconductor materials and/or dopants, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, dopants thereof, or any combination thereof. Although a few examples of materials from which the substrate 102 may be formed are described herein, any material that may serve as a foundation upon which passive and active electronic devices (e.g., memories, transistors, capacitors, inductors, resistors, switches, integrated circuits, amplifiers, optoelectronic devices, or any other electronic devices) may be fabricated is within the spirit and scope of the present disclosure. In one or more examples, the substrate 102 may be or contain silicon, a silicon germanium compound, a silicon germanium carbon compound, or any dopant thereof.

Each of the first silicon-germanium layer 110 and the second silicon-germanium layer 130 independently contains a silicon-germanium material which includes at least silicon and germanium. The silicon-germanium material may be doped or undoped. In one or more embodiments, each of the first silicon-germanium layer 110, the second silicon-germanium layer 130, and/or the silicon-germanium material independently contains a concentration of germanium in a range from about 5 atomic percent (at %), about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the first silicon-germanium layer 110, the second silicon-germanium layer 130, and/or the silicon-germanium material independently contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

In some embodiments, each of the first silicon-germanium layer 110, the second silicon-germanium layer 130, and/or the silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the first silicon-germanium layer 110, the second silicon-germanium layer 130, and/or the silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

In one or more examples, each of the first silicon-germanium layer 110, the second silicon-germanium layer 130, and/or the silicon-germanium material independently contains about 10 at % to about 30 at % of germanium and about 70 at % to about 90 at % of silicon. In some examples, each of the first silicon-germanium layer 110, the second silicon-germanium layer 130, and/or the silicon-germanium material independently contains about 10 at % to about 20 at % of germanium and about 80 at % to about 90 at % of silicon. In other examples, each of the first silicon-germanium layer 110, the second silicon-germanium layer 130, and/or the silicon-germanium material independently contains about 15 at % to about 25 at % of germanium and about 75 at % to about 85 at % of silicon.

In one or more embodiments, each of the first silicon-germanium layer 110 and the second silicon-germanium layer 130 independently has a thickness in a range from about 0.5 nm, about 1 nm, about 2 nm, about 3 nm, about 4 nm, or about 5 nm to about 6 nm, about 7 nm, about 8 nm, about 9 nm, about 10 nm, about 12 nm, about 15 nm, or thicker. For example, each of the first silicon-germanium layer 110 and the second silicon-germanium layer 130 independently has a thickness of about 0.5 nm to about 15 nm, about 1 nm to about 10 nm, about 1 nm to about 8 nm, about 1 nm to about 8 nm, about 1 nm to about 5 nm, about 1 nm to about 4 nm, about 1 nm to about 3 nm, about 2 nm to about 10 nm, about 4 nm to about 10 nm, about 5 nm to about 10 nm, about 6 nm to about 10 nm, about 8 nm to about 10 nm, or about 10 nm to about 12 nm.

In one or more examples, the dopant is an interstitial dopant, such as interstitial carbon and/or interstitial boron contained within the silicon-germanium material. In other examples, the dopant is a substitutional dopant, such as substitutional carbon and/or substitutional boron contained within the silicon-germanium material. In some examples, the dopant may be both an interstitial dopant and a substitutional dopant, such as substitutional and interstitial carbon and/or substitutional and interstitial boron contained within the silicon-germanium material.

The doped-silicon-germanium layer 120 contains dopant-silicon-germanium material which includes at least silicon, germanium, and one or more dopants (e.g., carbon, boron, or a combination of carbon and boron). The dopant-silicon-germanium material may be doped or undoped. In one or more embodiments, each of the doped-silicon-germanium layer 120 and/or the dopant-silicon-germanium material independently contains a concentration of germanium in a range from about 1 at %, about 2 at %, about 3 at %, about 4 at %, about 5 at %, about 6 at %, about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the doped-silicon-germanium layer 120 and/or the dopant-silicon-germanium material independently contains about 5 at % to about 40 at %, about 3 at % to about 35 at %, about 3 at % to about 30 at %, about 3 at % to about 25 at %, about 3 at % to about 20 at %, about 3 at % to about 15 at %, about 3 at % to about 10 at %, about 3 at % to about 8 at %, about 3 at % to about 6 at %, about 3 at % to about 5 at %, about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

Each of the doped-silicon-germanium layer 120 and/or the dopant-silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the doped-silicon-germanium layer 120 and/or the dopant-silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

Each of the doped-silicon-germanium layer 120 and/or the dopant-silicon-germanium material independently contains a concentration of dopant (e.g., carbon, boron, or a combination of carbon and boron) in a range from about 0.01 at %, about 0.05 at %, about 0.08 at %, about 0.1 at %, about 0.2 at %, about 0.3 at %, about 0.4 at %, about 0.5 at %, about 0.6 at %, about 0.8 at %, or about 1 at % to about 1.2 at %, about 1.5 at %, about 1.8 at %, about 2 at %, about 2.2 at %, about 2.5 at %, about 2.8 at %, about 3 at %, about 3.5 at %, about 4 at %, about 4.5 at %, or about 5 at %. For example, each of the doped-silicon-germanium layer 120 and/or the dopant-silicon-germanium material independently contains about 5 at % or less, about 0.01 at % to about 5 at %, about 0.01 at % to about 3 at %, about 0.01 at % to about 2 at %, about 0.01 at % to about 1 at %, about 0.01 at % to about 0.5 at %, about 0.1 at % to about 5 at %, about 0.1 at % to about 4 at %, about 0.1 at % to about 3.5 at %, about 0.1 at % to about 3 at %, about 0.1 at % to about 2.5 at %, about 0.1 at % to about 2 at %, about 0.1 at % to about 1.8 at %, about 0.1 at % to about 1.5 at %, about 0.1 at % to about 1.2 at %, about 0.1 at % to about 1 at %, about 0.1 at % to about 0.8 at %, about 0.1 at % to about 0.5 at %, about 0.2 at % to about 5 at %, about 0.2 at % to about 4 at %, about 0.2 at % to about 3.5 at %, about 0.2 at % to about 3 at %, about 0.2 at % to about 2.5 at %, about 0.2 at % to about 2 at %, about 0.2 at % to about 1.8 at %, about 0.2 at % to about 1.5 at %, about 0.2 at % to about 1.2 at %, about 0.2 at % to about 1 at %, about 0.2 at % to about 0.8 at %, about 0.2 at % to about 0.5 at %, about 0.5 at % to about 5 at %, about 0.5 at % to about 4 at %, about 0.5 at % to about 3.5 at %, about 0.5 at % to about 3 at %, about 0.5 at % to about 2.5 at %, about 0.5 at % to about 2 at %, about 0.5 at % to about 1.8 at %, about 0.5 at % to about 1.5 at %, about 0.5 at % to about 1.2 at %, about 0.5 at % to about 1 at %, about 0.5 at % to about 0.8 at %, about 1 at % to about 5 at %, about 1 at % to about 4 at %, about 1 at % to about 3.5 at %, about 1 at % to about 3 at %, about 1 at % to about 2.5 at %, about 1 at % to about 2 at %, about 1 at % to about 1.8 at %, about 1 at % to about 1.5 at %, about 1 at % to about 1.2 at % of dopant (e.g., carbon, boron, or a combination of carbon and boron).

In one or more examples, each of the doped-silicon-germanium layer 120 and/or the dopant-silicon-germanium material independently contains about 70 at % to about 95 at % of silicon, about 30 at % or less (e.g., about 3 at % to about 30 at %) of germanium, and about 5 at % or less (e.g., about 0.1 at % to about 2 at %) of carbon. In other examples, each of the doped-silicon-germanium layer 120 and/or the dopant-silicon-germanium material independently contains about 70 at % to about 90 at % of silicon, about 10 at % to about 30 at % of germanium, and about 0.2 at % to about 3 at % of carbon. In some examples, each of the doped-silicon-germanium layer 120 and/or the dopant-silicon-germanium material independently contains about 75 at % to about 85 at % of silicon, about 15 at % to about 25 at % of germanium, and about 0.5 at % to about 1.5 at % of carbon. In other examples, each of the doped-silicon-germanium layer 120 and/or the dopant-silicon-germanium material independently contains about 78 at % to about 82 at % of silicon, about 18 at % to about 22 at % of germanium, and about 0.8 at % to about 1.2 at % of carbon.

In one or more examples, each of the doped-silicon-germanium layer 120 and/or the dopant-silicon-germanium material independently contains about 70 at % to about 95 at % of silicon, about 30 at % or less (e.g., about 3 at % to about 30 at %) of germanium, and about 5 at % or less (e.g., about 0.1 at % to about 2 at %) of boron. In other examples, each of the doped-silicon-germanium layer 120 and/or the dopant-silicon-germanium material independently contains about 70 at % to about 90 at % of silicon, about 10 at % to about 30 at % of germanium, and about 0.2 at % to about 3 at % of boron. In some examples, each of the doped-silicon-germanium layer 120 and/or the dopant-silicon-germanium material independently contains about 75 at % to about 85 at % of silicon, about 15 at % to about 25 at % of germanium, and about 0.5 at % to about 1.5 at % of boron. In other examples, each of the doped-silicon-germanium layer 120 and/or the dopant-silicon-germanium material independently contains about 78 at % to about 82 at % of silicon, about 18 at % to about 22 at % of germanium, and about 0.8 at % to about 1.2 at % of boron.

In one or more examples, each of the doped-silicon-germanium layer 120 and/or the dopant-silicon-germanium material independently contains about 70 at % to about 95 at % of silicon, about 30 at % or less (e.g., about 3 at % to about 30 at %) of germanium, and about 5 at % or less (e.g., about 0.1 at % to about 2 at %) of a combination of carbon and boron. In other examples, each of the doped-silicon-germanium layer 120 and/or the dopant-silicon-germanium material independently contains about 70 at % to about 90 at % of silicon, about 10 at % to about 30 at % of germanium, and about 0.2 at % to about 3 at % of a combination of carbon and boron. In some examples, each of the doped-silicon-germanium layer 120 and/or the dopant-silicon-germanium material independently contains about 75 at % to about 85 at % of silicon, about 15 at % to about 25 at % of germanium, and about 0.5 at % to about 1.5 at % of a combination of carbon and boron. In other examples, each of the doped-silicon-germanium layer 120 and/or the dopant-silicon-germanium material independently contains about 78 at % to about 82 at % of silicon, about 18 at % to about 22 at % of germanium, and about 0.8 at % to about 1.2 at % of a combination of carbon and boron.

In one or more embodiments, the doped-silicon-germanium layer 120 has a thickness in a range from about 0.5 nm, about 1 nm, about 2 nm, about 3 nm, about 4 nm, about 5 nm, about 6 nm, about 8 nm, or about 10 nm to about 12 nm, about 14 nm, about 15 nm, about 16 nm, about 18 nm, about 20 nm, about 25 nm, or thicker. For example, each of the first silicon-germanium layer 110 and the second silicon-germanium layer 130 independently has a thickness of about 0.5 nm to about 25 nm, about 0.5 nm to about 20 nm, about 0.5 nm to about 15 nm, about 1 nm to about 25 nm, about 1 nm to about 20 nm, about 1 nm to about 15 nm, about 1 nm to about 10 nm, about 1 nm to about 8 nm, about 1 nm to about 8 nm, about 1 nm to about 5 nm, about 1 nm to about 4 nm, about 1 nm to about 3 nm, about 5 nm to about 25 nm, about 5 nm to about 20 nm, about 5 nm to about 15 nm, about 5 nm to about 10 nm, about 5 nm to about 8 nm, about 5 nm to about 8 nm, about 5 nm to about 7 nm, about 10 nm to about 25 nm, about 10 nm to about 20 nm, about 10 nm to about 15 nm, about 10 nm to about 12 nm, about 2 nm to about 10 nm, about 4 nm to about 10 nm, about 5 nm to about 10 nm, about 6 nm to about 10 nm, about 8 nm to about 10 nm, or about 10 nm to about 12 nm.

The doped silicon germanium stack 104 has a thickness in a range from about 1 nm, about 2 nm, about 3 nm, about 5 nm, about 6 nm, about 8 nm, or about 10 nm to about 12 nm, about 15 nm, about 18 nm, about 20 nm, about 25 nm, about 30 nm, about 40 nm, about 50 nm, or thicker. For example, the doped silicon germanium stack 104 has a thickness of about 1 nm to about 50 nm, about 5 nm to about 50 nm, about 5 nm to about 40 nm, about 5 nm to about 35 nm, about 5 nm to about 30 nm, about 5 nm to about 25 nm, about 5 nm to about 20 nm, about 5 nm to about 18 nm, about 5 nm to about 15 nm, about 5 nm to about 10 nm, about 5 nm to about 8 nm, about 10 nm to about 50 nm, about 10 nm to about 40 nm, about 10 nm to about 35 nm, about 10 nm to about 30 nm, about 10 nm to about 25 nm, about 10 nm to about 20 nm, about 10 nm to about 18 nm, about 10 nm to about 15 nm, about 10 nm to about 12 nm, about 15 nm to about 50 nm, about 15 nm to about 40 nm, about 15 nm to about 35 nm, about 15 nm to about 30 nm, about 15 nm to about 25 nm, about 15 nm to about 20 nm, or about 15 nm to about 18 nm.

The epitaxial-silicon layer 140 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the epitaxial-silicon layer 140 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

In one or more embodiments, the multi-layered epitaxial stack 108 has a dopant gradient based on the concentration of the dopant within each of the doped-silicon-germanium layers 120 such that the multi-layered epitaxial stack 108 has a wafer bow value of less than 600 μm. The multi-layered epitaxial stack 108 may have a wafer bow value of 0 μm, about 1 μm, about 5μm, about 10 μm, about 15 μm, about 20 μm, about 30 μm, about 40 μm, about 50 μm, about 60 μm, about 80 μm, or about 100 μm to about 120 μm, about 150 μm, about 180 μm, about 200 μm, about 250 μm, about 300 μm, about 350 μm, about or less than 400 μm, about or less than 450 μm, about or less than 500 μm, about or less than 550 μm, or about or less than 600 μm. In one or more examples, the multi-layered epitaxial stack 108 may have a wafer bow value of 0 μm to about or less than 600 μm, 0 μm to about 550 μm, about 10 μm to about or less than 550 μm, 0 μm to about 500 μm, about 10 μm to about or less than 500 μm, about 10 μm to about or less than 400 μm, about 10 μm to about or less than 350 μm, about 10 μm to about or less than 300 μm, about 10 μm to about or less than 250 μm, about 10 μm to about or less than 200 μm, about 10 μm to about or less than 175 μm, about 10 μm to about or less than 150 μm, about 10 μm to about or less than 125 μm, about 10 μm to about or less than 100 μm, about 10 μm to about or less than 80 μm, about 10 μm to about or less than 65 μm, about 10 μm to about or less than 50 μm, about 10 μm to about or less than 40 μm, about 10 μm to about or less than 20 μm, about 50 μm to about or less than 600 μm, about 50 μm to about or less than 500 μm, about 50 μm to about or less than 400 μm, about 50 μm to about or less than 350 μm, about 50 μm to about or less than 300 μm, about 50 μm to about or less than 250 μm, about 50 μm to about or less than 200 μm, about 50 μm to about or less than 175 μm, about 50 μm to about or less than 150 μm, about 50 μm to about or less than 125 μm, about 50 μm to about or less than 100 μm, about 50 μm to about or less than 80 μm, about 50 μm to about or less than 65 μm, about 100 μm to about or less than 600 μm, about 100 μm to about or less than 500 μm, about 100 μm to about or less than 400 μm, about 100 μm to about or less than 350 μm, about 100 μm to about or less than 300 μm, about 100 μm to about or less than 250 μm, about 100 μm to about or less than 200 μm, about 100 μm to about or less than 175 μm, about 100 μm to about or less than 150 μm, or about 100 μm to about or less than 125 μm.

FIG. 1 depicts the multi-layered epitaxial stack 108 containing three the doped silicon-germanium and silicon mini-stacks 106 disposed on the substrate 102. However, the multi-layered epitaxial stack 108 may have a variety of different amounts of the doped silicon-germanium and silicon mini-stack 106 disposed on the substrate 102. The multi-layered epitaxial stack 108 may contain a range from 1 stack, 2 stacks, 3 stacks, 4 stacks, 5 stacks, 6 stacks, 7 stacks, 8 stacks, about 10 stacks, about 12 stacks, about 15 stacks, about 18 stacks, about 20 stacks, about 25 stacks, about 30 stacks, about 35 stacks, about 40 stacks, about 45 stacks, or about 50 stacks to about 55 stacks, about 60 stacks, about 70 stacks, about 80 stacks, about 90 stacks, about 100 stacks, about 110 stacks, about 120 stacks, about 130 stacks, about 140 stacks, about 150 stacks, about 160 stacks, about 170 stacks, about 180 stacks, about 190 stacks, about 200 stacks, about 220 stacks, about 250 stacks, about 300 stacks, or more of the doped silicon-germanium and silicon mini-stack 106. For example, the multi-layered epitaxial stack 108 may contain about 2 stacks to about 300 stacks, about 5 stacks to about 250 stacks, about 10 stacks to about 200 stacks, about 20 stacks to about 200 stacks, about 30 stacks to about 200 stacks, about 35 stacks to about 200 stacks, about 40 stacks to about 200 stacks, about 50 stacks to about 200 stacks, about 60 stacks to about 200 stacks, about 80 stacks to about 200 stacks, about 100 stacks to about 200 stacks, about 120 stacks to about 200 stacks, about 150 stacks to about 200 stacks, about 180 stacks to about 200 stacks, about 10 stacks to about 100 stacks, about 20 stacks to about 100 stacks, about 30 stacks to about 100 stacks, about 35 stacks to about 100 stacks, about 40 stacks to about 100 stacks, about 50 stacks to about 100 stacks, about 60 stacks to about 100 stacks, about 80 stacks to about 100 stacks, about 90 stacks to about 100 stacks, about 10 stacks to about 90 stacks, about 10 stacks to about 80 stacks, about 10 stacks to about 70 stacks, about 10 stacks to about 60 stacks, about 10 stacks to about 50 stacks, about 10 stacks to about 40 stacks, about 10 stacks to about 35 stacks, about 10 stacks to about 30 stacks, about 10 stacks to about 25 stacks, about 10 stacks to about 20 stacks, or about 10 stacks to about 15 stacks of the doped silicon-germanium and silicon mini-stack 106. In one or more examples, the multi-layered epitaxial stack 108 contains about 10 stacks to about 200 stacks of the plurality of doped silicon-germanium and silicon mini-stacks 106. In some examples, the multi-layered epitaxial stack 108 contains about 30 stacks to about 100 stacks of the plurality of doped silicon-germanium and silicon mini-stacks 106. In other examples, the multi-layered epitaxial stack 108 contains about 35 stacks to about 75 stacks of the plurality of doped silicon-germanium and silicon mini-stacks 106.

In one or more embodiments, a workpiece 100 is provided and contains a multi-layered epitaxial stack 108 disposed on a substrate 102, and the multi-layered epitaxial stack 108 contains a plurality of doped silicon-germanium and silicon mini-stacks 106. Each of the doped silicon-germanium and silicon mini-stacks 106 contains a doped silicon germanium stack 104 and an epitaxial-silicon layer 140. Each of the doped silicon germanium stack 104 contains a doped-silicon-germanium layer 120 disposed between a first silicon-germanium layer 110 and a second silicon-germanium layer 130. Each of the doped-silicon-germanium layers 120 independently contains a concentration of a dopant in a range from about 0.01 at % to about 5 at %, and the dopant contains carbon, boron, or a combination of carbon and boron. The multi-layered epitaxial stack 108 has a dopant gradient based on the concentration of the dopant within each of the doped-silicon-germanium layers 120 such that the multi-layered epitaxial stack 108 has a wafer bow value of less than 600 μm or less than 500 μm. In some examples, the multi-layered epitaxial stack 108 has a wafer bow value of about 10 μm to about or less than 500 μm, about 10 μm to about or less than 400 μm, about 10 μm to about or less than 300 μm, about 10μm to about or less than 200 μm, or about 10 μm to about or less than 150 μm.

In other embodiments, a workpiece 100 is provided and contains a multi-layered epitaxial stack 108 disposed on a substrate 102, where the multi-layered epitaxial stack 108 contains a plurality of doped silicon-germanium and silicon mini-stacks 106 which contains about 10 stacks to about 250 stacks, for example, about 30 stacks to about 100 stacks. Each of the doped silicon-germanium and silicon mini-stacks 106 contains a doped silicon germanium stack 104 and an epitaxial-silicon layer 140. Each of the doped silicon germanium stack 104 contains a doped-silicon-germanium layer 120 disposed between a first silicon-germanium layer 110 and a second silicon-germanium layer 130. Each of the doped-silicon-germanium layers 120 independently contains a concentration of a dopant in a range from about 0.01 at % to about 3 at % and the dopant contains carbon, boron, or a combination of carbon and boron. The multi-layered epitaxial stack 108 has a dopant gradient based on the concentration of the dopant within each of the doped-silicon-germanium layers 120 such that the multi-layered epitaxial stack 108 has a wafer bow value of less than 300 μm. In some examples, the multi-layered epitaxial stack 108 has a wafer bow value of or less than 200 μm, such as less than 100 μm.

In one or more embodiments, a method of fabricating a film stack is provided and includes sequentially depositing a doped silicon germanium stack 104 and an epitaxial-silicon layer 140 to form a doped silicon-germanium and silicon mini-stack disposed on a substrate 102 during a deposition cycle, and repeating the deposition cycle to prepare a multi-layered epitaxial stack 108 containing a plurality of the doped silicon-germanium and silicon mini-stacks 106 on the substrate 102. Each of the doped silicon germanium stacks 104 contains a doped-silicon-germanium layer 120 disposed between a first silicon-germanium layer 110 and a second silicon-germanium layer 130. Each of the doped-silicon-germanium layers 120 independently contains a concentration of a dopant in a range from about 0.01 at % to about 5 at %, and the dopant contains carbon, boron, or a combination of carbon and boron. The multi-layered epitaxial stack 108 has a dopant gradient based on the concentration of the dopant within each of the doped-silicon-germanium layers 120 such that the multi-layered epitaxial stack 108 has a wafer bow value of less than 600 μm.

In one or more embodiments, the multi-layered epitaxial stack 108 has a dopant gradient based on the concentration of the dopant within each of the doped-silicon-germanium layers 120 as determined and adjusted at operations 220 and 222 of the methods 200.

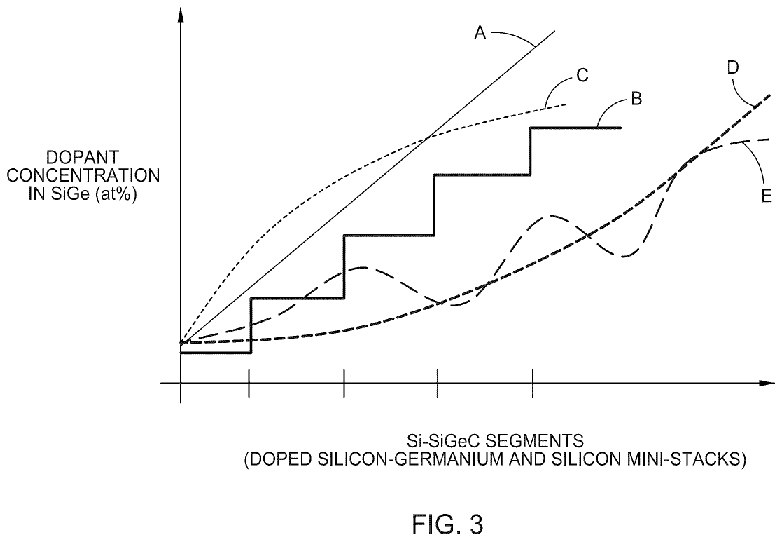

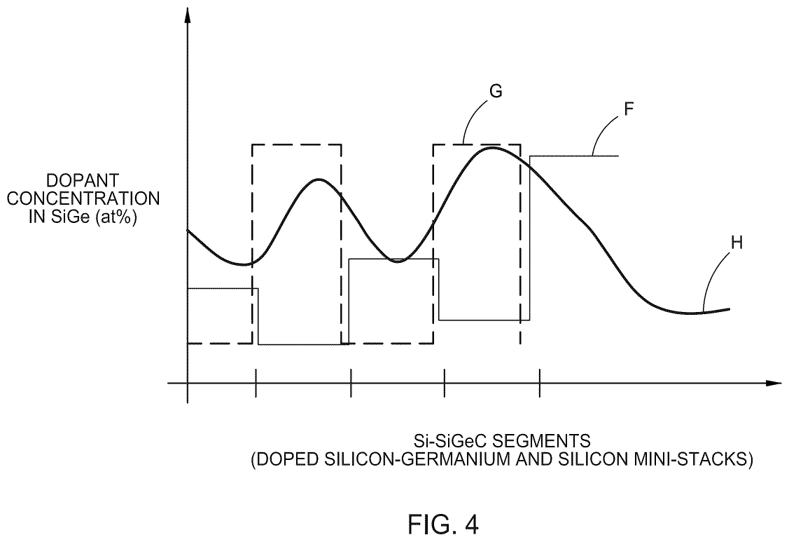

FIGS. 3 and 4 are graphs depicting a carbon concentration across a plurality of doped silicon-germanium and silicon mini-stacks in the five Examples A-E (FIG. 3) and in the three Examples F-H (FIG. 4), according to embodiments described and discussed herein. Each of the doped-silicon-germanium layers 120 may independently have a dopant concentration which is equal to, less than, or greater than any of the neighboring doped-silicon-germanium layers 120. In each of the Examples A-H, the dopant concentration varies in order to provide the multi-layered epitaxial stack 108 containing a dopant gradient based on the concentration of the dopant within each of the doped-silicon-germanium layers 120. Each of the doped silicon-germanium and silicon mini-stacks 106 contains a Si-SiGeC segment throughout the multi-layered epitaxial stack 108. As such, the multi-layered epitaxial stack 108 may contain about 2 stacks to about 300 stacks of the Si-SiGeC segments or the doped silicon-germanium and silicon mini-stacks 106.

In Example A of FIG. 3, the dopant concentration has a value which linearly increases or substantially linearly increases across the multi-layered epitaxial stack 108 away from the substrate 102 so to provide a linearly or substantially linearly dopant gradient based on the concentration of the dopant within each of the doped-silicon-germanium layers 120 across the multi-layered epitaxial stack 108.

In Example B of FIG. 3, the dopant concentration has a first value which is constant through a first group of the doped-silicon-germanium layers 120, then vertically increases to a second value greater than the first value and stays constant through a second group of the doped-silicon-germanium layers 120, then vertically increases to a third value greater than the second value and stays constant through a third group of the doped-silicon-germanium layers 120, then vertically increases to a fourth value greater than the third value and stays constant through a fourth group of the doped-silicon-germanium layers 120, then vertically increases to a fifth value greater than the fourth value and stays constant through a fifth group of the doped-silicon-germanium layers 120, and continues as such to provide an increasing stair-step pattern dopant gradient away from the substrate 102 based on the concentration of the dopant within each of the doped-silicon-germanium layers 120 across the multi-layered epitaxial stack 108.

In Example C of FIG. 3, the dopant concentration increases at a decreasing rate across the multi-layered epitaxial stack 108 away from the substrate 102 so to provide a positive curved dopant gradient (or an upwardly curved dopant gradient) based on the concentration of the dopant within each of the doped-silicon-germanium layers 120 across the multi-layered epitaxial stack 108.

In Example D of FIG. 3, the dopant concentration increases at an increasing rate across the multi-layered epitaxial stack 108 away from the substrate 102 so to provide a negative curved dopant gradient (or a downwardly curved dopant gradient) based on the concentration of the dopant within each of the doped-silicon-germanium layers 120 across the multi-layered epitaxial stack 108.

In Example E of FIG. 3, the dopant concentration increases at a decreasing rate across the multi-layered epitaxial stack 108 from the substrate 102 so to provide a upwardly curved dopant gradient, then the dopant concentration decreases at a rate across the multi-layered epitaxial stack 108 from the substrate 102 so to provide a downwardly curved dopant gradient, but stays greater than the beginning concentration, then the dopant concentration increases at a decreasing rate across the multi-layered epitaxial stack 108 from the substrate 102 so to provide another upwardly curved dopant gradient, then the dopant concentration decreases at a rate across the multi-layered epitaxial stack 108 away from the substrate 102 so to provide another downwardly curved dopant gradient, but stays greater than the ending concentration of the previous downwardly curved dopant gradient. In one or more examples, the concentration of the dopant has sequential maximum points and minimum points, such that each of the peaks (or maximum points) of the dopant concentration is greater than the immediately previous peak (or maximum point) of the dopant concentration relative from the substrate 102 and/or each of the valleys (or minimum points) of the dopant concentration is greater than the immediately previous valley (or minimum point) of the dopant concentration relative from the substrate 102. These peaks and valley in dopant concentration may be repeated as many times as desired to provide an overall increasing dopant gradient of peaks and valleys based on the concentration of the dopant within each of the doped-silicon-germanium layers 120 across the multi-layered epitaxial stack 108.

In Example F of FIG. 4, the dopant concentration has a first value which is constant through a first group of the doped-silicon-germanium layers 120, then vertically decreases to a second value less than the first value and stays constant through a second group of the doped-silicon-germanium layers 120, then vertically increases to a third value greater than the first value and stays constant through a third group of the doped-silicon-germanium layers 120, then vertically decreases to a fourth value greater than the second value and less than the third value and stays constant through a fourth group of the doped-silicon-germanium layers 120, then vertically increases to a fifth value greater than the third value and stays constant through a fifth group of the doped-silicon-germanium layers 120, and continues as such to provide an increasing stair-step pattern dopant gradient based on the concentration of the dopant within each of the doped-silicon-germanium layers 120 across the multi-layered epitaxial stack 108. For example, each of the maximum or peak dopant concentration values progressively increase away from the substrate 102 and each of the minimum or valley dopant concentration values progressively increase away from the substrate 102.

In Example G of FIG. 4, the dopant concentration has a first value which is constant through a first group of the doped-silicon-germanium layers 120, then vertically increases to a second value greater than the first value and stays constant through a second group of the doped-silicon-germanium layers 120, then vertically decreases to a third value equal to the first value and stays constant through a third group of the doped-silicon-germanium layers 120, then vertically increases to a fourth value equal to the second value and stays constant through a fourth group of the doped-silicon-germanium layers 120, then vertically decreases to a fifth value equal to the third value and stays constant through a fifth group of the doped-silicon-germanium layers 120, and continues as such to provide an increasing-decreasing pattern dopant gradient based on the concentration of the dopant within each of the doped-silicon-germanium layers 120 across the multi-layered epitaxial stack 108. For example, the concentration of the dopant has sequential maximum points which are linearly constant across multiple segments of the doped-silicon-germanium layers 120 and minimum points which are linearly constant across multiple segments of the doped-silicon-germanium layers 120. The maximum points of the concentration of the dopant have the same value, the minimum points of the concentration of the dopant have the same value which is less than the value of the maximum points.

In Example H of FIG. 4, the dopant concentration decreases at a rate across the multi-layered epitaxial stack 108 from the substrate 102 so to provide a downwardly curved dopant gradient, then the dopant concentration increases at a rate across the multi-layered epitaxial stack 108 from the substrate 102 so to provide an upwardly curved dopant gradient, but is greater than the beginning concentration, then the dopant concentration decreases at a rate across the multi-layered epitaxial stack 108 so to provide another downwardly curved dopant gradient, then the dopant concentration increases at a rate across the multi-layered epitaxial stack 108 so to provide another upwardly curved dopant gradient greater than the previous peak of dopant concentration, then the dopant concentration decreases at a rate across the multi-layered epitaxial stack 108 so to provide another downwardly curved dopant gradient which is lower than the previous valley of dopant concentration. In one or more examples, each of the valleys (or minimum point) of the dopant concentration is equal to or less than the immediately previous valley (or minimum point) of the dopant concentration, and each of the peaks (or high point) of the dopant concentration is equal to or greater than the immediately previous peak (or high point) of the dopant concentration. These peaks and valley in dopant concentration may be repeated as many times as desired to provide an overall increasing or decreasing dopant gradient of peaks and valleys based on the concentration of the dopant within each of the doped-silicon-germanium layers 120 across the multi-layered epitaxial stack 108.

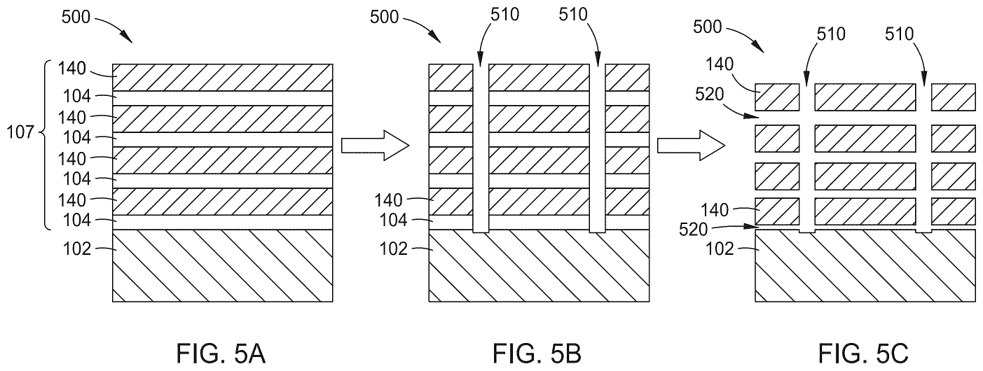

FIGS. 5A-5C depict a process flow of a workpiece 500 containing a multi-layered epitaxial stack 108 disposed on a substrate 102 being processed to remove the doped silicon germanium stacks 104 retain the epitaxial-silicon layers 140, according to one or more embodiments described and discussed herein. In one or more examples, the workpiece 500 may be the workpiece 100, as described and discussed above. In other examples, the workpiece 500 may contain alternative configurations of stacks, layers, and/or films. The remaining epitaxial-silicon layers 140 may be utilized in the structure of one or more types of memory devices, transistor devices, and/or other microelectronic devices. In one or more examples, the memory device is a three-dimensional, dynamic random access memory (3D-DRAM) structure/device or a 3D-NAND structure/device. In other examples, the remaining epitaxial-silicon layers 140 may be utilized as channels of transistors.

FIG. 5A depicts the workpiece 500 containing the multi-layered epitaxial stack 108 disposed on a substrate 102, according to one or more embodiments described and discussed herein. The multi-layered epitaxial stack 108 contains a plurality of or two, three, four, or more of doped silicon-germanium and silicon mini-stacks (four stacks are shown), each containing alternating films of a doped silicon germanium stack 104 and an epitaxial-silicon layer 140.

FIG. 5B depicts the workpiece 500 after having trenches 510 formed through the multi-layered epitaxial stack 108. The trenches 510 may be fabricated or otherwise formed in the multi-layered epitaxial stack 108 by one or more etching processes. In some examples, a mask may be disposed or otherwise formed on the upper surface of the multi-layered epitaxial stack 108 and the exposed portions of the multi-layered epitaxial stack 108 may be removed via one or more wet etching processes (e.g., acid etch process) and/or one or more dry etching processes (e.g., plasma etch process).

FIG. 5C depicts the workpiece 500 after having the doped silicon germanium stacks 104 etched or otherwise removed while retaining the epitaxial-silicon layers 140. Passageways or channels 520 are formed between the epitaxial-silicon layers 140 in place of the doped silicon germanium stacks 104. The doped silicon germanium stacks 104 may be selectively etched one or more wet etching processes. The wet etching process may be one-step or multi-step process. In one or more examples, the wet etching process may be an HF/SC1 wet etching process, where the workpiece 500 is exposed to an hydrofluoric acid solution and subsequently to a SC1 solution containing ammonium hydroxide, hydrogen peroxide, and water. Once the doped silicon germanium stacks 104 are etched away or otherwise removed, the workpiece 500 containing the epitaxial-silicon layers 140, as shown in FIG. 5C, can be used in a memory device, such as a 3D-DRAM structure/device or a 3D-NAND structure/device.

Most traditional chemical vapor deposition (CVD) chambers or atomic layer deposition (ALD) chambers may be used as the processing chamber suitable for performing the vapor deposition processes described and discussed herein. An example of a tool or system that may benefit from the vapor deposition processes described and discussed herein is the Centura® system or Endura® system with an iSprint™ ALD/CVD SSW chamber, commercially available from Applied Materials, Inc.

Embodiments of the present disclosure further relate to any one or more of the following Clauses 1-95:
Clause 1. A workpiece, comprising: a multi-layered epitaxial stack disposed on a substrate, wherein: the multi-layered epitaxial stack comprises a plurality of doped silicon-germanium and silicon mini-stacks; each of the doped silicon-germanium and silicon mini-stacks comprises a doped silicon germanium stack and an epitaxial-silicon layer; and each of the doped silicon germanium stack comprises a doped-silicon-germanium layer disposed between a first silicon-germanium layer and a second silicon-germanium layer, wherein: each of the doped-silicon-germanium layers independently comprises a concentration of a dopant in a range from about 0.01 atomic percent (at %) to about 5 at %; the dopant comprises carbon, boron, or a combination of carbon and boron; and the multi-layered epitaxial stack has a dopant gradient based on the concentration of the dopant within each of the doped-silicon-germanium layers.
Clause 2. The workpiece according to Clause 1, wherein the concentration of the dopant has a value which linearly increases or substantially linearly increases across the multi-layered epitaxial stack away from the substrate so to provide a linearly or substantially linearly dopant gradient based on the concentration of the dopant within each of the doped-silicon-germanium layers across the multi-layered epitaxial stack.
Clause 3. The workpiece according to Clause 1 or 2, wherein the concentration of the dopant has an increasing stair-step pattern dopant gradient away from the substrate based on the concentration of the dopant within each of the doped-silicon-germanium layers across the multi-layered epitaxial stack.
Clause 4. The workpiece according to any one of Clauses 1-3, wherein the concentration of the dopant increases at a decreasing rate across the multi-layered epitaxial stack away from the substrate so to provide a positive curved dopant gradient or an upwardly curved dopant gradient based on the concentration of the dopant within each of the doped-silicon-germanium layers across the multi-layered epitaxial stack.
Clause 5. The workpiece according to any one of Clauses 1-4, wherein the concentration of the dopant increases at an increasing rate across the multi-layered epitaxial stack away from the substrate so to provide a negative curved dopant gradient or a downwardly curved dopant gradient based on the concentration of the dopant within each of the doped-silicon-germanium layers across the multi-layered epitaxial stack.
Clause 6. The workpiece according to any one of Clauses 1-5, wherein the concentration of the dopant has sequential maximum points and minimum points, each of the maximum points of the dopant concentration is greater than the immediately previous maximum point of the dopant concentration relative from the substrate and/or each of the minimum points of the dopant concentration is greater than the immediately previous minimum point of the dopant concentration relative from the substrate.
Clause 7. The workpiece according to any one of Clauses 1-6, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein the maximum points of the concentration of the dopant have the same value, the minimum points of the concentration of the dopant have the same value which is less than the value of the maximum points.
Clause 8. The workpiece according to any one of Clauses 1-7, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein each of the maximum points have values progressively increasing away from the substrate and each of the minimum points have values progressively increasing away from the substrate.
Clause 9. The workpiece according to any one of Clauses 1-8, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein the maximum points of the concentration of the dopant have the same value, the minimum points of the concentration of the dopant have the same value which is less than the value of the maximum points.
Clause 10. The workpiece according to any one of Clauses 1-9, wherein the doped silicon germanium stack has a thickness in a range from about 5 nm to about 20 nm.
Clause 11. The workpiece according to any one of Clauses 1-10, wherein each of the first silicon-germanium layer and the second silicon-germanium layer independently has a thickness in a range from about 1 nm to about 10 nm.
Clause 12. The workpiece according to any one of Clauses 1-11, wherein the doped-silicon-germanium layer has a thickness in a range from about 1 nm to about 20 nm.
Clause 13. The workpiece according to any one of Clauses 1-12, wherein the epitaxial-silicon layer has a thickness in a range from about 10 nm to about 150 nm.
Clause 14. The workpiece according to any one of Clauses 1-13, wherein the multi-layered epitaxial stack has a wafer bow value of less than 600 μm.
Clause 15. The workpiece according to any one of Clauses 1-14, wherein the multi-layered epitaxial stack has a wafer bow value of about 10 μm to about or less than 500 μm.
Clause 16. The workpiece according to any one of Clauses 1-15, wherein the multi-layered epitaxial stack has a wafer bow value of about 10 μm to about or less than 300 μm, about 10 μm to about or less than 200 μm, or about 10 μm to about or less than 150 μm.
Clause 17. The workpiece according to any one of Clauses 1-16, wherein the plurality of doped silicon-germanium and silicon mini-stacks contains about 10 stacks to about 250 stacks.
Clause 18. The workpiece according to any one of Clauses 1-17, wherein the plurality of doped silicon-germanium and silicon mini-stacks contains about 30 stacks to about 100 stacks.
Clause 19. The workpiece according to any one of Clauses 1-18, wherein the substrate comprises silicon, a silicon germanium compound, or a dopant thereof.
Clause 20. The workpiece according to any one of Clauses 1-19, wherein each of the first silicon-germanium layer and the second silicon-germanium layer independently comprises about 20 at % or less of germanium.
Clause 21. The workpiece according to any one of Clauses 1-20, wherein each of the first silicon-germanium layer and the second silicon-germanium layer independently comprises about 10 at % to about 20 at % of germanium and about 80 at % to about 90 at % of silicon.
Clause 22. The workpiece according to any one of Clauses 1-21, wherein the doped-silicon-germanium layer comprises about 30 at % or less of germanium and about 5 at % or less of the dopant.
Clause 23. The workpiece according to any one of Clauses 1-22, wherein the doped-silicon-germanium layer comprises about 70 at % to about 95 at % of silicon, about 3 at % to about 30 at % of germanium, and about 0.1 at % to about 2 at % of the dopant.
Clause 24. A method of fabricating a film stack, comprising: sequentially depositing a doped silicon germanium stack and an epitaxial-silicon layer to form a doped silicon-germanium and silicon mini-stack disposed on a substrate during a deposition cycle; and repeating the deposition cycle to prepare a multi-layered epitaxial stack comprising a plurality of the doped silicon-germanium and silicon mini-stacks on the substrate, wherein: each of the doped silicon germanium stacks comprises a doped-silicon-germanium layer disposed between a first silicon-germanium layer and a second silicon-germanium layer; each of the doped-silicon-germanium layers independently comprises a concentration of a dopant in a range from about 0.01 atomic percent (at %) to about 5 at %; the dopant comprises carbon, boron, or a combination of carbon and boron; and the multi-layered epitaxial stack has a dopant gradient based on the concentration of the dopant within each of the doped-silicon-germanium layers.
Clause 25. The method according to Clause 24, wherein the concentration of the dopant has a value which linearly increases or substantially linearly increases across the multi-layered epitaxial stack away from the substrate so to provide a linearly or substantially linearly dopant gradient based on the concentration of the dopant within each of the doped-silicon-germanium layers across the multi-layered epitaxial stack.
Clause 26. The method according to Clause 24 or 25, wherein the concentration of the dopant has an increasing stair-step pattern dopant gradient away from the substrate based on the concentration of the dopant within each of the doped-silicon-germanium layers across the multi-layered epitaxial stack.
Clause 27. The method according to any one of Clauses 24-26, wherein the concentration of the dopant increases at a decreasing rate across the multi-layered epitaxial stack away from the substrate so to provide a positive curved dopant gradient or an upwardly curved dopant gradient based on the concentration of the dopant within each of the doped-silicon-germanium layers across the multi-layered epitaxial stack.
Clause 28. The method according to any one of Clauses 24-27, wherein the concentration of the dopant increases at an increasing rate across the multi-layered epitaxial stack away from the substrate so to provide a negative curved dopant gradient or a downwardly curved dopant gradient based on the concentration of the dopant within each of the doped-silicon-germanium layers across the multi-layered epitaxial stack.
Clause 29. The method according to any one of Clauses 24-28, wherein the concentration of the dopant has sequential maximum points and minimum points, each of the maximum points of the dopant concentration is greater than the immediately previous maximum point of the dopant concentration relative from the substrate and/or each of the minimum points of the dopant concentration is greater than the immediately previous minimum point of the dopant concentration relative from the substrate.
Clause 30. The method according to any one of Clauses 24-29, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein the maximum points of the concentration of the dopant have the same value, the minimum points of the concentration of the dopant have the same value which is less than the value of the maximum points.
Clause 31. The method according to any one of Clauses 24-30, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein each of the maximum points have values progressively increasing away from the substrate and each of the minimum points have values progressively increasing away from the substrate.
Clause 32. The method according to any one of Clauses 24-31, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein the maximum points of the concentration of the dopant have the same value, the minimum points of the concentration of the dopant have the same value which is less than the value of the maximum points.
Clause 33. The method according to any one of Clauses 24-32, wherein the deposition cycle is repeated from about 10 times to about 250 times to prepare the multi-layered epitaxial stack.
Clause 34. The method according to any one of Clauses 24-33, wherein the deposition cycle is repeated from about 30 times to about 100 times to prepare the multi-layered epitaxial stack.
Clause 35. The method according to any one of Clauses 24-34, wherein the deposition cycle comprises: exposing a workpiece comprising the substrate to a first gas comprising a silicon precursor, a silicon-chlorine precursor, a germanium precursor, a chloride precursor, and a carrier gas to deposit a first silicon-germanium layer; starting a flow of a dopant precursor; exposing the workpiece to a second gas comprising the silicon precursor, the silicon-chlorine precursor, the dopant precursor, the germanium precursor, the chloride precursor, and the carrier gas to deposit a doped-silicon-germanium layer on the first silicon-germanium layer; ceasing the flow of the dopant precursor; exposing the workpiece to a third gas comprising the silicon precursor, the silicon-chlorine precursor, the germanium precursor, the chloride precursor, and the carrier gas to deposit a second silicon-germanium layer on the doped-silicon-germanium layer; ceasing a flow of the germanium precursor and the chloride precursor; exposing the workpiece to a fourth gas comprising the silicon precursor, the silicon-chlorine precursor, and the carrier gas to deposit the epitaxial-silicon layer on the second silicon-germanium layer; ceasing a flow of the silicon-chlorine precursor; and exposing the workpiece to a fifth gas comprising the silicon precursor and the carrier gas to continue depositing the epitaxial-silicon layer on the second silicon-germanium layer.
Clause 36. The method according to any one of Clauses 24-35, wherein the dopant precursor comprises a carbon precursor, a silicon-carbon precursor, or a combination of the carbon precursor and the silicon-carbon precursor.
Clause 37. The method according to any one of Clauses 24-36, wherein the silicon-carbon precursor comprises one or more alkylsilanes.
Clause 38. The method according to any one of Clauses 24-37, wherein the silicon-carbon comprises monomethylsilane, dimethylsilane, or any combination thereof.
Clause 39. The method according to any one of Clauses 24-38, wherein the dopant precursor comprises a boron precursor.
Clause 40. The method according to any one of Clauses 24-39, wherein the boron precursor comprises diborane, trimethylborane, triethylborane, boron trichloride, or any combination thereof.
Clause 41. The method according to any one of Clauses 24-40, wherein the dopant precursor comprises a carbon precursor, a silicon-carbon precursor, a boron precursor, or any combination thereof.
Clause 42. The method according to any one of Clauses 24-41, wherein the chloride precursor comprises hydrogen chloride, chlorine (Cl₂), or any combination thereof.
Clause 43. The method according to any one of Clauses 24-42, wherein the silicon precursor comprises silane, disilane, trisilane, tetrasilane, or any combination thereof.
Clause 44. The method according to any one of Clauses 24-43, wherein the silicon-chlorine precursor comprises monochlorosilane, dichlorosilane, trichlorosilane, tetracholorosilane, hexachlorodisilane, or any combination thereof.
Clause 45. The method according to any one of Clauses 24-44, wherein the germanium precursor comprises germane, digermane, or a combination thereof.
Clause 46. The method according to any one of Clauses 24-45, wherein the carrier gas comprises hydrogen (H₂), nitrogen (N₂), argon, helium, or any combination thereof.
Clause 47. The method according to any one of Clauses 24-46, wherein the carrier gas comprises hydrogen (H₂) and nitrogen (N₂) having a hydrogen to nitrogen molar ratio in a range from about 1:10 to about 10:1.
Clause 48. The method according to any one of Clauses 24-47, wherein the substrate comprises silicon, a silicon germanium compound, or a dopant thereof.
Clause 49. The method according to any one of Clauses 24-48, wherein the doped silicon germanium stack has a thickness in a range from about 5 nm to about 20 nm.
Clause 50. The method according to any one of Clauses 24-49, wherein each of the first silicon-germanium layer and the second silicon-germanium layer independently has a thickness in a range from about 1 nm to about 10 nm.
Clause 51. The method according to any one of Clauses 24-50, wherein the doped-silicon-germanium layer has a thickness in a range from about 1 nm to about 20 nm.
Clause 52. The method according to any one of Clauses 24-51, wherein the epitaxial-silicon layer has a thickness in a range from about 10 nm to about 150 nm.
Clause 53. The method according to any one of Clauses 24-52, wherein the multi-layered epitaxial stack has a wafer bow value of less than 600 μm.
Clause 54. The method according to any one of Clauses 24-53, wherein the multi-layered epitaxial stack has a wafer bow value of about 10 μm to less than 500 μm.
Clause 55. The method according to any one of Clauses 24-54, wherein the multi-layered epitaxial stack has a wafer bow value of about 10 μm to about or less than 300 μm, about 10 μm to about or less than 200 μm, or about 10 μm to about or less than 150 μm.
Clause 56. The method according to any one of Clauses 24-55, wherein each of the first silicon-germanium layer and the second silicon-germanium layer independently comprises about 20 at % or less of germanium.
Clause 57. The method according to any one of Clauses 24-56, wherein each of the first silicon-germanium layer and the second silicon-germanium layer independently comprises about 10 at % to about 20 at % of germanium and about 80 at % to about 90 at % of silicon.
Clause 58. The method according to any one of Clauses 24-57, wherein the doped-silicon-germanium layer comprises about 30 at % or less of germanium and about 5 at % or less of the dopant.
Clause 59. The method according to any one of Clauses 24-58, wherein the doped-silicon-germanium layer comprises about 70 at % to about 95 at % of silicon, about 3 at % to about 30 at % of germanium, and about 0.1 at % to about 2 at % of the dopant.
Clause 60. A workpiece, comprising: a multi-layered epitaxial stack disposed on a substrate, wherein: the multi-layered epitaxial stack comprises a plurality of doped silicon-germanium and silicon mini-stacks which contains about 10 stacks to about 250 stacks; each of the doped silicon-germanium and silicon mini-stacks comprises a doped silicon germanium stack and an epitaxial-silicon layer; and each of the doped silicon germanium stack comprises a doped-silicon-germanium layer disposed between a first silicon-germanium layer and a second silicon-germanium layer, wherein: each of the doped-silicon-germanium layers independently comprises a concentration of a dopant in a range from about 0.01 atomic percent (at %) to about 3 at %; the dopant comprises carbon, boron, or a combination of carbon and boron; and the multi-layered epitaxial stack has a dopant gradient based on the concentration of the dopant within each of the doped-silicon-germanium layers.
Clause 61. The workpiece according to Clause 60, wherein the concentration of the dopant has a value which linearly increases or substantially linearly increases across the multi-layered epitaxial stack away from the substrate so to provide a linearly or substantially linearly dopant gradient based on the concentration of the dopant within each of the doped-silicon-germanium layers across the multi-layered epitaxial stack.
Clause 62. The workpiece according to Clause 60 or 61, wherein the concentration of the dopant has an increasing stair-step pattern dopant gradient away from the substrate based on the concentration of the dopant within each of the doped-silicon-germanium layers across the multi-layered epitaxial stack.
Clause 63. The workpiece according to any one of Clauses 60-62, wherein the concentration of the dopant increases at a decreasing rate across the multi-layered epitaxial stack away from the substrate so to provide a positive curved dopant gradient or an upwardly curved dopant gradient based on the concentration of the dopant within each of the doped-silicon-germanium layers across the multi-layered epitaxial stack.
Clause 64. The workpiece according to any one of Clauses 60-63, wherein the concentration of the dopant increases at an increasing rate across the multi-layered epitaxial stack away from the substrate so to provide a negative curved dopant gradient or a downwardly curved dopant gradient based on the concentration of the dopant within each of the doped-silicon-germanium layers across the multi-layered epitaxial stack.
Clause 65. The workpiece according to any one of Clauses 60-64, wherein the concentration of the dopant has sequential maximum points and minimum points, each of the maximum points of the dopant concentration is greater than the immediately previous maximum point of the dopant concentration relative from the substrate and/or each of the minimum points of the dopant concentration is greater than the immediately previous minimum point of the dopant concentration relative from the substrate.
Clause 66. The workpiece according to any one of Clauses 60-65, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein the maximum points of the concentration of the dopant have the same value, the minimum points of the concentration of the dopant have the same value which is less than the value of the maximum points.
Clause 67. The workpiece according to any one of Clauses 60-66, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein each of the maximum points have values progressively increasing away from the substrate and each of the minimum points have values progressively increasing away from the substrate.
Clause 68. The workpiece according to any one of Clauses 60-67, wherein the concentration of the dopant has sequential maximum points and minimum points, wherein the maximum points are linearly constant across multiple segments of the doped-silicon-germanium layers and the minimum points are linearly constant across multiple segments of the doped-silicon-germanium layers, and wherein the maximum points of the concentration of the dopant have the same value, the minimum points of the concentration of the dopant have the same value which is less than the value of the maximum points.
Clause 69. The workpiece according to any one of Clauses 60-68, wherein the multi-layered epitaxial stack has a wafer bow value of or less than 300 μm, less than 200 μm, or less than 100 μm.
Clause 70. The workpiece according to any one of Clauses 60-69, wherein the plurality of doped silicon-germanium and silicon mini-stacks contains about 30 stacks to about 100 stacks.
Clause 71. A film stack, comprising: a plurality of mini-stacks disposed on a substrate, each mini-stack comprising: a first silicon-containing layer; a doped silicon-containing layer over the first silicon-containing layer, the doped silicon-containing layer comprising a dopant; a second silicon-containing layer over the doped silicon-containing layer; and a silicon layer over the second silicon-containing layer; wherein the dopant has a gradient across the mini-stacks such that a concentration of dopant in the doped silicon-containing layer is different between a first film stack and a second film stack of the plurality of mini-stacks.
Clause 72. The film stack according to Clause 71, wherein the first silicon-containing layer is a first epitaxial silicon germanium layer, the doped silicon-containing layer is a doped epitaxial silicon germanium layer, and the second silicon-containing layer is a second epitaxial silicon germanium layer.
Clause 73. The film stack according to Clause 71 or 72, wherein the dopant is carbon having a concentration in a range from about 0.01 atomic percent (at %) to about 5 at %.
Clause 74. The film stack according to any one of Clauses 71-73, wherein the concentration of the dopant has a value which linearly increases or substantially linearly increases across the plurality of mini-stacks away from the substrate so to provide a linearly or substantially linearly dopant gradient based on the concentration of the dopant within each of the doped silicon-containing layer across the plurality of mini-stacks.
Clause 75. The film stack according to any one of Clauses 71-74, wherein the concentration of the dopant has an increasing stair-step pattern dopant gradient away from the substrate based on the concentration of the dopant within each of the doped silicon-containing layer across the plurality of mini-stacks.
Clause 76. The film stack according to any one of Clauses 71-75, wherein the concentration of the dopant increases at a decreasing rate across the plurality of mini-stacks away from the substrate so to provide a positive curved dopant gradient or an upwardly curved dopant gradient based on the concentration of the dopant within each of the doped silicon-containing layer across the plurality of mini-stacks.
Clause 77. The film stack according to any one of Clauses 71-76, wherein the concentration of the dopant increases at an increasing rate across the plurality of mini-stacks away from the substrate so to provide a negative curved dopant gradient or a downwardly curved dopant gradient based on the concentration of the dopant within each of the doped silicon-containing layer across the plurality of mini-stacks.
Clause 78. The film stack according to any one of Clauses 71-77, wherein the concentration of the dopant has sequential maximum points and minimum points, each of the maximum points of the dopant concentration is greater than the immediately previous maximum point of the dopant concentration relative from the substrate and/or each of the minimum points of the dopant concentration is greater than the immediately previous minimum point of the dopant concentration relative from the substrate.
Clause 79. The film stack according to any one of Clauses 71-78, wherein the concentration of the dopant has sequential maximum points and minimum points, wherein the maximum points are linearly constant across multiple segments of the doped silicon-containing layer and the minimum points are linearly constant across multiple segments of the doped silicon-containing layer, and wherein the maximum points of the concentration of the dopant have the same value, the minimum points of the concentration of the dopant have the same value which is less than the value of the maximum points.
Clause 80. The film stack according to any one of Clauses 71-79, wherein the concentration of the dopant has sequential maximum points and minimum points, wherein the maximum points are linearly constant across multiple segments of the doped silicon-containing layer and the minimum points are linearly constant across multiple segments of the doped silicon-containing layer, and wherein each of the maximum points have values progressively increasing away from the substrate and each of the minimum points have values progressively increasing away from the substrate.
Clause 81. The film stack according to any one of Clauses 71-80, wherein the concentration of the dopant has sequential maximum points and minimum points, wherein the maximum points are linearly constant across multiple segments of the doped silicon-containing layer and the minimum points are linearly constant across multiple segments of the doped silicon-containing layer, and wherein the maximum points of the concentration of the dopant have the same value, the minimum points of the concentration of the dopant have the same value which is less than the value of the maximum points.
Clause 82. The film stack according to any one of Clauses 71-81, wherein a doped silicon germanium stack comprises the doped silicon-containing layer disposed between the first silicon-containing layer and the second silicon-containing layer, and wherein the doped silicon germanium stack has a thickness in a range from about 5 nm to about 20 nm.
Clause 83. The film stack according to any one of Clauses 71-82, wherein each of the first silicon-containing layer and the second silicon-containing layer independently has a thickness in a range from about 1 nm to about 10 nm.
Clause 84. The film stack according to any one of Clauses 71-83, wherein the doped-silicon-containing layer has a thickness in a range from about 1 nm to about 20 nm.
Clause 85. The film stack according to any one of Clauses 71-84, wherein the silicon layer has a thickness in a range from about 10 nm to about 150 nm.
Clause 86. The film stack according to any one of Clauses 71-85, wherein the plurality of mini-stacks has a wafer bow value of less than 600 μm.
Clause 87. The film stack according to any one of Clauses 71-86, wherein the plurality of mini-stacks has a wafer bow value of about 10 μm to about or less than 500 μm.
Clause 88. The film stack according to any one of Clauses 71-87, wherein the plurality of mini-stacks has a wafer bow value of about 10 μm to about or less than 300 μm, about 10 μm to about or less than 200 μm, or about 10 μm to about or less than 150 μm.
Clause 89. The film stack according to any one of Clauses 71-88, wherein the plurality of mini-stacks contains about 10 stacks to about 250 stacks.
Clause 90. The film stack according to any one of Clauses 71-89, wherein the plurality of mini-stacks contains about 30 stacks to about 100 stacks.
Clause 91. The film stack according to any one of Clauses 71-90, wherein the substrate comprises silicon, a silicon germanium compound, or a dopant thereof.
Clause 92. The film stack according to any one of Clauses 71-91, wherein each of the first silicon-containing layer and the second silicon-containing layer independently comprises about 20 at % or less of germanium.
Clause 93. The film stack according to any one of Clauses 71-92, wherein each of the first silicon-containing layer and the second silicon-containing layer independently comprises about 10 at % to about 20 at % of germanium and about 80 at % to about 90 at % of silicon.
Clause 94. The film stack according to any one of Clauses 71-93, wherein the doped-silicon-containing layer comprises about 30 at % or less of germanium and about 5 at % or less of the dopant.
Clause 95. The film stack according to any one of Clauses 71-94, wherein the doped-silicon-containing layer comprises about 70 at % to about 95 at % of silicon, about 3 at % to about 30 at % of germanium, and about 0.1 at % to about 2 at % of the dopant.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications may be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation may be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A workpiece, comprising:
a multi-layered epitaxial stack disposed on a substrate, wherein:
the multi-layered epitaxial stack comprises a plurality of doped silicon-germanium and silicon mini-stacks;
each of the doped silicon-germanium and silicon mini-stacks comprises a doped silicon germanium stack and an epitaxial-silicon layer; and
each of the doped silicon germanium stack comprises a doped-silicon-germanium layer disposed between a first silicon-germanium layer and a second silicon-germanium layer, wherein:
each of the doped-silicon-germanium layers independently comprises a concentration of a dopant in a range from about 0.01 atomic percent (at %) to about 5 at %;
the dopant comprises carbon, boron, or a combination of carbon and boron; and
the multi-layered epitaxial stack has a dopant gradient based on the concentration of the dopant within each of the doped-silicon-germanium layers.

2. The workpiece of claim 1, wherein the concentration of the dopant has a value which linearly increases or substantially linearly increases across the multi-layered epitaxial stack away from the substrate so to provide a linearly or substantially linearly dopant gradient based on the concentration of the dopant within each of the doped-silicon-germanium layers across the multi-layered epitaxial stack.

3. The workpiece of claim 1, wherein the concentration of the dopant has an increasing stair-step pattern dopant gradient away from the substrate based on the concentration of the dopant within each of the doped-silicon-germanium layers across the multi-layered epitaxial stack.

4. The workpiece of claim 1, wherein the concentration of the dopant increases at a decreasing rate across the multi-layered epitaxial stack away from the substrate so to provide a positive curved dopant gradient or an upwardly curved dopant gradient based on the concentration of the dopant within each of the doped-silicon-germanium layers across the multi-layered epitaxial stack.

5. The workpiece of claim 1, wherein the concentration of the dopant increases at an increasing rate across the multi-layered epitaxial stack away from the substrate so to provide a negative curved dopant gradient or a downwardly curved dopant gradient based on the concentration of the dopant within each of the doped-silicon-germanium layers across the multi-layered epitaxial stack.

6. The workpiece of claim 1, wherein:
the doped silicon germanium stack has a thickness in a range from about 5 nm to about 20 nm;
each of the first silicon-germanium layer and the second silicon-germanium layer independently has a thickness in a range from about 1 nm to about 10 nm;
the doped-silicon-germanium layer has a thickness in a range from about 1 nm to about 20 nm; and
the epitaxial-silicon layer has a thickness in a range from about 10 nm to about 150 nm.

7. The workpiece of claim 1, wherein the multi-layered epitaxial stack has a wafer bow value of less than 600 μm.

8. The workpiece of claim 1, wherein the plurality of doped silicon-germanium and silicon mini-stacks contains about 10 stacks to about 250 stacks.

9. The workpiece of claim 1, wherein each of the first silicon-germanium layer and the second silicon-germanium layer independently comprises about 10 at % to about 20 at % of germanium and about 80 at % to about 90 at % of silicon.

10. The workpiece of claim 1, wherein the doped-silicon-germanium layer comprises about 70 at % to about 95 at % of silicon, about 3 at % to about 30 at % of germanium, and about 0.1 at % to about 2 at % of the dopant.

11. A method of fabricating a film stack, comprising:
sequentially depositing a doped silicon germanium stack and an epitaxial-silicon layer to form a doped silicon-germanium and silicon mini-stack disposed on a substrate during a deposition cycle; and
repeating the deposition cycle to prepare a multi-layered epitaxial stack comprising a plurality of the doped silicon-germanium and silicon mini-stacks on the substrate, wherein:
each of the doped silicon germanium stacks comprises a doped-silicon-germanium layer disposed between a first silicon-germanium layer and a second silicon-germanium layer;
each of the doped-silicon-germanium layers independently comprises a concentration of a dopant in a range from about 0.01 atomic percent (at %) to about 5 at %;
the dopant comprises carbon, boron, or a combination of carbon and boron; and
the multi-layered epitaxial stack has a dopant gradient based on the concentration of the dopant within each of the doped-silicon-germanium layers.

12. The method of claim 11, wherein the deposition cycle is repeated from about 10 times to about 250 times to prepare the multi-layered epitaxial stack.

13. The method of claim 11, wherein the deposition cycle comprises:
exposing a workpiece comprising the substrate to a first gas comprising a silicon precursor, a silicon-chlorine precursor, a germanium precursor, a chloride precursor, and a carrier gas to deposit a first silicon-germanium layer;
starting a flow of a dopant precursor;
exposing the workpiece to a second gas comprising the silicon precursor, the silicon-chlorine precursor, the dopant precursor, the germanium precursor, the chloride precursor, and the carrier gas to deposit a doped-silicon-germanium layer on the first silicon-germanium layer;
ceasing the flow of the dopant precursor;
exposing the workpiece to a third gas comprising the silicon precursor, the silicon-chlorine precursor, the germanium precursor, the chloride precursor, and the carrier gas to deposit a second silicon-germanium layer on the doped-silicon-germanium layer;
ceasing a flow of the germanium precursor and the chloride precursor;
exposing the workpiece to a fourth gas comprising the silicon precursor, the silicon-chlorine precursor, and the carrier gas to deposit the epitaxial-silicon layer on the second silicon-germanium layer;
ceasing a flow of the silicon-chlorine precursor; and
exposing the workpiece to a fifth gas comprising the silicon precursor and the carrier gas to continue depositing the epitaxial-silicon layer on the second silicon-germanium layer.

14. The method of claim 13, wherein:
the dopant precursor comprises a silicon-carbon precursor, and the silicon-carbon precursor comprises one or more alkylsilanes; and
the dopant precursor comprises a boron precursor, and the boron precursor comprises diborane, trimethylborane, triethylborane, boron trichloride, or any combination thereof.

15. The method of claim 11, wherein:
the chloride precursor comprises hydrogen chloride, chlorine (Cl₂), or any combination thereof;
the silicon precursor comprises silane, disilane, trisilane, tetrasilane, or any combination thereof;
the silicon-chlorine precursor comprises monochlorosilane, dichlorosilane, trichlorosilane, tetracholorosilane, hexachlorodisilane, or any combination thereof; and
the germanium precursor comprises germane, digermane, or a combination thereof.

16. The method of claim 11, wherein:
the doped silicon germanium stack has a thickness in a range from about 5 nm to about 20 nm;
each of the first silicon-germanium layer and the second silicon-germanium layer independently has a thickness in a range from about 1 nm to about 10 nm;
the doped-silicon-germanium layer has a thickness in a range from about 1 nm to about 20 nm;
the epitaxial-silicon layer has a thickness in a range from about 10 nm to about 150 nm; and
the multi-layered epitaxial stack has a wafer bow value of less than 600 μm.

17. The method of claim 11, wherein each of the first silicon-germanium layer and the second silicon-germanium layer independently comprises about 10 at % to about 20 at % of germanium and about 80 at % to about 90 at % of silicon, and wherein the doped-silicon-germanium layer comprises about 70 at % to about 95 at % of silicon, about 3 at % to about 30 at % of germanium, and about 0.1 at % to about 2 at % of the dopant.

18. A film stack, comprising:
a plurality of mini-stacks disposed on a substrate, each mini-stack comprising:
a first silicon-containing layer;
a doped silicon-containing layer over the first silicon-containing layer, the doped silicon-containing layer comprising a dopant;
a second silicon-containing layer over the doped silicon-containing layer; and
a silicon layer over the second silicon-containing layer;
wherein the dopant has a gradient across the mini-stacks such that a concentration of dopant in the doped silicon-containing layer is different between a first film stack and a second film stack of the plurality of mini-stacks.

19. The film stack of claim 18, wherein the first silicon-containing layer is a first epitaxial silicon germanium layer, the doped silicon-containing layer is a doped epitaxial silicon germanium layer, and the second silicon-containing layer is a second epitaxial silicon germanium layer, and wherein the dopant is carbon having a concentration in a range from about 0.01 atomic percent (at %) to about 5 at %.

20. The film stack of claim 18, wherein:
the plurality of mini-stacks contains about 30 stacks to about 100 stacks;
each of the first silicon-containing layer and the second silicon-containing layer independently comprises about 10 at % to about 20 at % of germanium and about 80 at % to about 90 at % of silicon; and
the doped-silicon-containing layer comprises about 70 at % to about 95 at % of silicon, about 3 at % to about 30 at % of germanium, and about 0.1 at % to about 2 at % of the dopant.
